(19) United States
(12) Patent Application Publication
(10) Pub. No.: US 2026/0092939 A1
(43) Pub. Date: Apr. 2, 2026

(54) VEHICLE ASSEMBLY, TRANSMISSION UNIT, AND VEHICLE

(71) Applicant: Scania CV AB, Södertälje (SE)

(72) Inventor: Harshad KULKARNI, Huddinge (SE)

(73) Assignee: Scania CV AB, Södertälje (SE)

(21) Appl. No.: 19/113,588

(22) PCT Filed: Oct. 3, 2023
(86) PCT No.: PCT/SE2023/050980

§ 371 Date: Mar. 20, 2025

(30) Foreign Application Priority Data
Oct. 7, 2022 (SE) 2251166-1

(51) Int. Cl. G01P 1/02; G01P 3/488

(52) U.S. Cl. CPC G01P 1/026; G01P 3/488

(57) ABSTRACT

A vehicle assembly is disclosed comprising a vehicle member and a speed measuring arrangement for measuring a rotational speed of the vehicle member. The speed measuring arrangement comprises a set of elements arranged at a portion of the vehicle member and being configured to rotate in a first plane upon rotation of the vehicle member. The speed measuring arrangement further comprises a speed sensor unit comprising an end section facing the portion of the vehicle member from a first side of the first plane. The speed sensor unit comprises a Hall sensor arranged at the end section. The present disclosure further relates to a transmission unit comprising a vehicle assembly and a vehicle.

### CROSS-REFERENCE TO RELATED APPLICATIONS

This application is a national stage application (filed under 35 § U.S.C. 371) of PCT/SE2023/050980, filed Oct. 3, 2023 of the same title, which, in turn claims priority to Swedish Patent Application No. 2251166-1, filed on Oct. 7, 2022; the contents of each of which are hereby incorporated by reference.

### TECHNICAL FIELD

The present disclosure relates to vehicle assembly comprising a vehicle member configured to rotate around a rotation axis and a speed measuring arrangement for measuring a rotational speed of the vehicle member. The present disclosure further relates to a transmission unit comprising a vehicle assembly. Moreover, the present disclosure relates to a vehicle comprising a vehicle assembly.

### BACKGROUND

Various types of speed measuring arrangements are used in vehicles to measure the rotational speed of a vehicle member of the vehicle, such as a shaft of a gearbox of the vehicle, or the like. Data from these types of speed measuring arrangements can be used as an input in different types of onboard systems of the vehicle, such as in different control systems, driving aid systems, and the like.

The operation and functionality of such a system is usually highly dependent on the data from the speed measuring arrangement and incorrect data from a speed measuring arrangement normally leads to a major malfunction of the system. Therefore, a general problem when designing a speed measuring arrangement is that it is usually important to ensure that the speed measuring arrangement is able to provide reliable data indicative of the rotational speed of the vehicle member.

Some types of speed measuring arrangements utilize a wheel member with a number of ferromagnetic elements arranged around a circumference of the wheel member, and a sensor arranged in close proximity to a portion of the wheel member comprising the number of ferromagnetic elements. In such speed measuring arrangements, the sensor may be arranged to sense variations in magnetic flux density due to positional changes of the number of ferromagnetic elements of the wheel member. Such type of speed measuring arrangement is an efficient means of sensing the rotational speed of the wheel member. However, these types of speed measuring arrangements are also associated with some problems.

As an example, typically, this type of speed measuring arrangement is sensitive to changes in the relative distance between the sensor and the portion of the wheel member at which the number of ferromagnetic elements is arranged. Too small distances between the portion of the wheel member and the sensor may cause an impact therebetween which can damage the sensor, whereas too large distances between the sensor and the portion of the wheel member may reduce the accuracy and reliability of the data from the sensor. Accordingly, both of these cases may result in an inability to measure the rotational speed of the wheel member.

Moreover, this type of speed measuring arrangement, as well as other types of speed measuring arrangements, may be sensitive to vibration and oscillations. As an example, if the speed measuring arrangement is utilized to measure the rotational speed of a shaft, such as a shaft of a gearbox, an idling engine, or other type of unit or arrangement of the vehicle, may cause the shaft to oscillate and/or vibrate. If such oscillation and/or vibration is transferred to the wheel member, it can cause the sensor to sense variations in magnetic flux density which resembles variations in magnetic flux density obtained during rotation of the wheel member. A control arrangement connected to the sensor may interpret such variations in magnetic flux density as rotation of the wheel member. Accordingly, such erroneous data from a sensor can have major impact on the operation and functionality of a system utilizing data from the sensor.

Technical development has led to an increased number of systems and components packed into vehicles. The increased number of systems and components of modern vehicles can lead to packing problems, i.e., problems in fitting and arranging all components and systems of the vehicle in an efficient manner. Therefore, another general problem when designing a speed measuring arrangement is that it may be difficult to fit the speed measuring arrangement together with other types of components and systems of the vehicle in an efficient manner.

### SUMMARY

It is an object of the present invention to overcome, or at least alleviate, at least some of the above-mentioned problems and drawbacks.

According to a first aspect of the invention, the object is achieved by a vehicle assembly comprising a vehicle member configured to rotate around a rotation axis, at least occasionally, during operation of a vehicle comprising the vehicle assembly. The vehicle assembly further comprises a speed measuring arrangement for measuring a rotational speed of the vehicle member. The speed measuring arrangement comprises a set of elements arranged at a portion of the vehicle member, wherein the set of elements is configured to rotate in a first plane upon rotation of the vehicle member around the rotation axis, and a speed sensor unit comprising an end section facing the portion of the vehicle member from a first side of the first plane. The speed sensor unit comprises a Hall sensor arranged at the end section of the speed sensor unit.

Since the end section of the speed sensor unit faces the portion of the vehicle member from the first side of the first plane and since the speed sensor unit comprises the Hall sensor arranged at the end section of the speed sensor unit, a vehicle assembly is provided having conditions for measuring the rotational speed of the vehicle member in a robust and reliable manner while allowing for a mounting of the speed sensor unit at a distance from the portion of the vehicle member measured in a direction parallel to the rotation axis of the vehicle member.

The feature that the end section of the speed sensor unit faces the portion of the vehicle member from the first side of the first plane means that the speed sensor unit is arranged at least partially axially relative to the vehicle member. Since the vehicle assembly comprises the Hall sensor arranged at the end section of the speed sensor unit, the at least partially axial arrangement of the speed sensor unit relative to the vehicle member can be used while being able to measure the rotational speed of the vehicle member in a robust and reliable manner.

Accordingly, due to these features, a vehicle assembly is provided having conditions for measuring the rotational speed of the vehicle member in a robust and reliable manner while being able to alleviate packing problems in a vehicle comprising the vehicle assembly.

Accordingly, a vehicle assembly is provided overcoming, or at least alleviating, at least some of the above-mentioned problems and drawbacks. As a result, the above-mentioned object is achieved.

Optionally, the speed sensor unit comprises a magnet, and wherein the Hall sensor is arranged between the magnet and the portion of the vehicle member. Thereby, a vehicle assembly is provided having conditions for measuring the rotational speed of the vehicle member in a robust and reliable manner while being able to alleviate packing problems in a vehicle comprising the vehicle assembly.

Optionally, the magnet provides a magnetic flux density at the end section exceeding 35 Gauss or exceeding 40 Gauss. Thereby, a vehicle assembly is provided having conditions for a relatively large distance between the end section of the speed sensor unit and the portion of the vehicle member. In this manner, at least small variations in the axial position of the vehicle member are allowed while allowing the at least partially axial arrangement of the speed sensor unit relative to the vehicle member. Variations in the axial position of the vehicle members can for example occur in gearboxes of vehicles, and the like.

Optionally, an angle between a normal vector to the first plane and a magnetic axis of the magnet is less than 30 degrees or is less than 10 degrees. Thereby, packing problems in a vehicle comprising the vehicle assembly can be alleviated while conditions are provided for a robust and reliable measurement of the rotational speed of the vehicle member.

Optionally, a magnetic axis of the magnet extends through the Hall sensor and the portion of the vehicle member. Thereby, conditions are provided for measuring the rotational speed of the vehicle member in a robust, accurate, and reliable manner while allowing for a mounting of the speed sensor unit at a distance from the portion of the vehicle member measured in a direction parallel to the rotation axis of the vehicle member. Moreover, due to these features, a vehicle assembly is provided having conditions for being less sensitive to variations in the relative distance between the end section of the speed sensor unit and the portion of the vehicle member.

Optionally, the magnet is arranged at a distance from the Hall sensor measured along a direction perpendicular to the first plane. Thereby, conditions are provided for a speed measuring arrangement being less sensitive to vibration and oscillation of the vehicle member. This is because a more concentrated concentric part of the magnetic field of the magnet can interact with elements in a more accurate and focused manner while avoiding interference from elements located further from the concentrated concentric part of the magnetic field.

Optionally, the distance between the magnet and the Hall sensor is within the range of 1-7 mm or is within the range of 2.5-5.5 mm. Thereby, conditions are provided for a speed measuring arrangement being less sensitive to vibration and oscillation of the vehicle member. This is because a more concentrated concentric part of the magnetic field of the magnet can interact with elements in a more accurate and focused manner while avoiding interference from elements located further from the concentrated concentric part of the magnetic field.

Optionally, the distance between the magnet and the Hall sensor is within the range of 10%-230%, or is within the range of 85%-165%, of a distance between the Hall sensor and the portion of the vehicle member, measured along a direction perpendicular to the first plane. Thereby, conditions are provided for a speed measuring arrangement being less sensitive to vibration and oscillation of the vehicle member. This is because a more concentrated concentric part of the magnetic field of the magnet can interact with elements in a more accurate and focused manner while avoiding interference from elements located further from the concentrated concentric part of the magnetic field.

Optionally, the distance between the magnet and the Hall sensor is greater than a distance between the Hall sensor and the portion of the vehicle member, measured along a direction perpendicular to the first plane. Thereby, conditions are provided for a speed measuring arrangement being less sensitive to vibration and oscillation of the vehicle member. This is because a more concentrated concentric part of the magnetic field of the magnet can interact with elements in a more accurate and focused manner while avoiding interference from elements located further from the concentrated concentric part of the magnetic field.

Optionally, the distance between the magnet and the Hall sensor is greater than a thickness of the portion of the vehicle member, measured along a direction perpendicular to the first plane. Thereby, conditions are provided for a speed measuring arrangement being less sensitive to vibration and oscillation of the vehicle member. This is because a more concentrated concentric part of the magnetic field of the magnet can interact with elements in a more accurate and focused manner while avoiding interference from elements located further from the concentrated concentric part of the magnetic field.

Optionally, the speed sensor unit comprises an elongated sensor portion being elongated along a direction of elongation and comprising the end section, and wherein the angle between the direction of elongation of the elongated sensor portion and a normal vector to the first plane is less than 30 degrees or is less than 10 degrees. Thereby, packing problems in a vehicle comprising the vehicle assembly can be alleviated while conditions are provided for a robust and reliable measurement of the rotational speed of the vehicle member.

Optionally, the speed sensor unit comprises an elongated sensor portion comprising the end section, and wherein the elongated sensor portion comprises a geometrical center axis parallel to a direction of elongation of the elongated sensor portion, and wherein the Hall sensor has a Hall sensor axis located a distance from the geometrical center axis of the elongated sensor portion. Thereby, conditions are provided for a compact speed sensor unit while a robust and reliable measurement of the rotational speed of the vehicle member can be provided. As a further result, a vehicle assembly is provided having conditions for alleviating packing problems in a vehicle comprising the vehicle assembly.

Optionally, the distance between the Hall sensor axis and the geometrical center axis is within the range of 0.3-10 mm or is within the range of 1-4 mm. Thereby, conditions are provided for a compact speed sensor unit while a robust and reliable measurement of the rotational speed of the vehicle member can be provided. As a further result, a vehicle assembly is provided having conditions for alleviating packing problems in a vehicle comprising the vehicle assembly.

Optionally, the vehicle assembly comprises a control unit and an electric circuit connecting the control unit to the Hall sensor, wherein the control unit is configured to provide data representative of the rotational speed of the vehicle member by monitoring a voltage of the Hall sensor. Thereby, a vehicle assembly is provided having conditions for providing data representative of the rotational speed of the vehicle member in a simple, robust, and reliable manner while allowing for a mounting of the speed sensor unit at a distance from the portion of the vehicle member measured in a direction parallel to the rotation axis of the vehicle member.

Optionally, each of the control unit and the electric circuit is arranged in the speed sensor unit. Thereby, a vehicle assembly is provided having conditions for measuring the rotational speed of the vehicle member in a simple, robust, and reliable manner while having conditions for alleviating packing problems in a vehicle comprising the vehicle assembly.

Optionally, the vehicle member of the vehicle assembly is configured to be connected to at least one ground engaging wheel of a vehicle comprising the vehicle assembly. Thereby, a vehicle assembly is provided having conditions for measuring the speed of the vehicle relative to a ground surface in a robust and reliable manner, while being able to alleviate packing problems in the vehicle.

According to a second aspect of the invention, the object is achieved by a transmission unit comprising a shaft configured to transmit power from a power source to at least one ground engaging wheel of a vehicle comprising the transmission unit, wherein the transmission unit comprises a vehicle assembly according to some embodiments of the present disclosure, and wherein the vehicle member of the vehicle assembly is connected to the shaft of the transmission unit.

Since the transmission unit comprises a vehicle assembly according to some embodiments, a transmission unit is provided overcoming, or at least alleviating, at least some of the above-mentioned problems and drawbacks. As a result, the above-mentioned object is achieved.

According to a third aspect of the invention, the object is achieved by a vehicle comprising a vehicle assembly according to some embodiments of the present disclosure, or a vehicle transmission unit according to some embodiments of the present disclosure.

Since the vehicle comprises a vehicle assembly according to some embodiments, or a vehicle transmission unit according to some embodiments, a vehicle is provided overcoming, or at least alleviating, at least some of the above-mentioned problems and drawbacks. As a result, the above-mentioned object is achieved.

Further features of, and advantages with, the present invention will become apparent when studying the appended claims and the following detailed description.

### BRIEF DESCRIPTION OF THE DRAWINGS

Various aspects of the invention, including its particular features and advantages, will be readily understood from the example embodiments discussed in the following detailed description and the accompanying drawings, in which:

FIG. 1 schematically illustrates a vehicle according to some embodiments of the present disclosure,

FIG. 2 schematically illustrated a powertrain of the vehicle illustrated in FIG. 1,

FIG. 3 illustrates a cross section of a vehicle assembly according to some embodiments of the vehicle illustrated in FIG. 1,

FIG. 4 illustrates an isometric view of a portion of the vehicle assembly illustrated in FIG. 3,

FIG. 5 illustrates an enlarged cross section of the vehicle assembly illustrated in FIG. 3 and FIG. 4,

FIG. 6 illustrates a sectional view of the vehicle assembly illustrated in FIG. 3-FIG. 5,

FIG. 7 illustrates an enlarged view of the sectional view of the vehicle assembly illustrated in FIG. 6,

FIG. 8 illustrates the enlarged view of the sectional view of the vehicle assembly illustrated in FIG. 7,

FIG. 9 illustrates a cross section of a vehicle assembly according to some further embodiments,

FIG. 10 illustrates an isometric view of a portion of the vehicle assembly illustrated in FIG. 9, and

FIG. 11 illustrates an enlarged cross section of the vehicle assembly illustrated in FIG. 9 and FIG. 10.

### DETAILED DESCRIPTION

Aspects of the present invention will now be described more fully. Like numbers refer to like elements throughout. Well-known functions or constructions will not necessarily be described in detail for brevity and/or clarity.

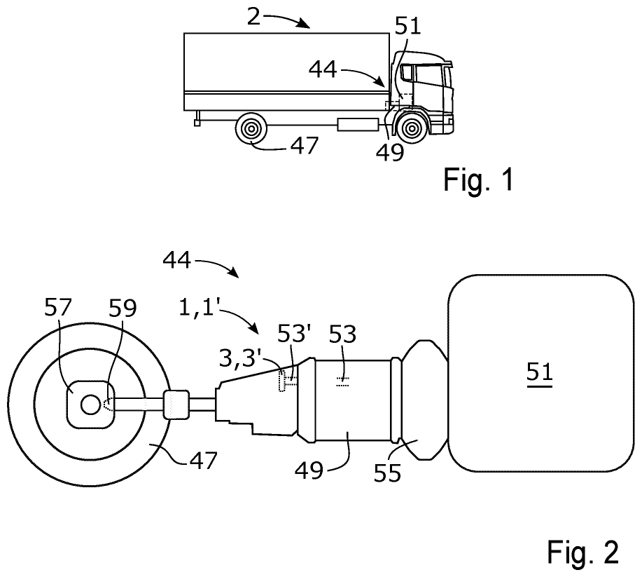

FIG. 1 schematically illustrates a vehicle 2 according to some embodiments of the present disclosure. According to the illustrated embodiments, the vehicle 2 is a truck, i.e., a type of heavy vehicle. According to further embodiments, the vehicle 2, as referred to herein, may be another type of manned or unmanned vehicle for land or water-based propulsion such as a lorry, a bus, a construction vehicle, a tractor, a car, a ship, a boat, or the like.

The vehicle 2 comprises a powertrain 44. The powertrain 44 comprises a power source 51 and a transmission unit 49. The transmission unit 49 is configured to transmit power from the power source 51 to at least one ground engaging wheel 47 of the vehicle 2. According to the illustrated embodiments, the power source 51 is an internal combustion engine. However, the vehicle 2 may comprise another type of power source, such as an electrical machine or the like, as an alternative to, or in addition to, the internal combustion engine.

Thus, the vehicle 2, as referred to herein, may comprise a so-called hybrid electric powertrain comprising one or more electric propulsion motors in addition to an internal combustion engine for providing motive power to the vehicle 2. Moreover, the vehicle 2, as referred to herein, may comprise a so-called fully electrical powertrain comprising no internal combustion engine for providing motive power to the vehicle 2.

FIG. 2 schematically illustrated the powertrain 44 of the vehicle 2 illustrated in FIG. 1. Below, simultaneous reference is made to FIG. 1-FIG. 2, if not indicated otherwise. As mentioned, the powertrain 44 comprises a power source 51 and a transmission unit 49, wherein the transmission unit 49 is configured to transmit power from the power source 51 to at least one ground engaging wheel 47 of the vehicle 2.

In more detail, according to the illustrated embodiments, the powertrain 44 comprises a clutch 55 positioned between the power source 51 and the transmission unit 49. The engagement state of the clutch 55 can be controlled in order to control the transfer of torque between the power source 51 and an input shaft of the transmission unit 49. According to the illustrated embodiments, the transmission unit 49 is a gearbox comprising different gears which provides different gear ratios between the input shaft of the transmission unit 49 and an output shaft 53′ of the transmission unit 49. According to further embodiments, the transmission unit 49 may be another type of transmission unit for transferring power from a power source 51 to at least one ground engaging wheel 47 of a vehicle.

The output shaft 53′ of the transmission unit 49 is connected to the at least one ground engaging wheel 47 such that the output shaft 53′ of the transmission unit 49 corotates with the at least one ground engaging wheel 47, i.e., such that output shaft 53′ of the transmission unit 49 rotates if the at least one ground engaging wheel 47 is rotating. As understood from the above, due to the features of the powertrain 44, the output shaft 53′ of the transmission unit 49 corotates with the at least one ground engaging wheel 47 regardless of a current engagement state of the clutch 55 and regardless of a current gear selected in the transmission unit 49. In other words, the output shaft 53′ of the transmission unit 49 rotates if the vehicle 2 is moving in a forward or reverse direction relative to a ground surface.

According to some embodiments, the at least one ground engaging wheel 47 illustrated in FIG. 2 represents a pair of ground engaging wheels 47. The ground engaging wheels 47 of the pair of ground engaging wheels 47 may be rotationally connected to each other via a differential gear 57. According to such embodiments, the output shaft 53′ of the transmission unit 49 may be connected to an input gear 59 of the differential gear 57 such that the output shaft 53′ of the transmission unit 49 corotates with the input gear 59 of the differential gear 57, i.e., such that output shaft 53′ of the transmission unit 49 rotates if the input gear 59 is rotating. Accordingly, also in such embodiments, the output shaft 53′ of the transmission unit 49 rotates if the vehicle 2 is moving in a forward or reverse direction relative to a ground surface.

According to the illustrated embodiments, the powertrain 44 of the vehicle 2 comprises a vehicle assembly 1. The vehicle assembly 1 comprises a vehicle member 3. According to the illustrated embodiments, the vehicle member 3 is connected to the output shaft 53′ of the transmission unit 49 and is arranged to corotate with the output shaft 53′ of the transmission unit 49. According to further embodiments, the vehicle member 3, as referred to herein, may be connected to another type of shaft 53 of a vehicle 2 comprising the vehicle assembly 1.

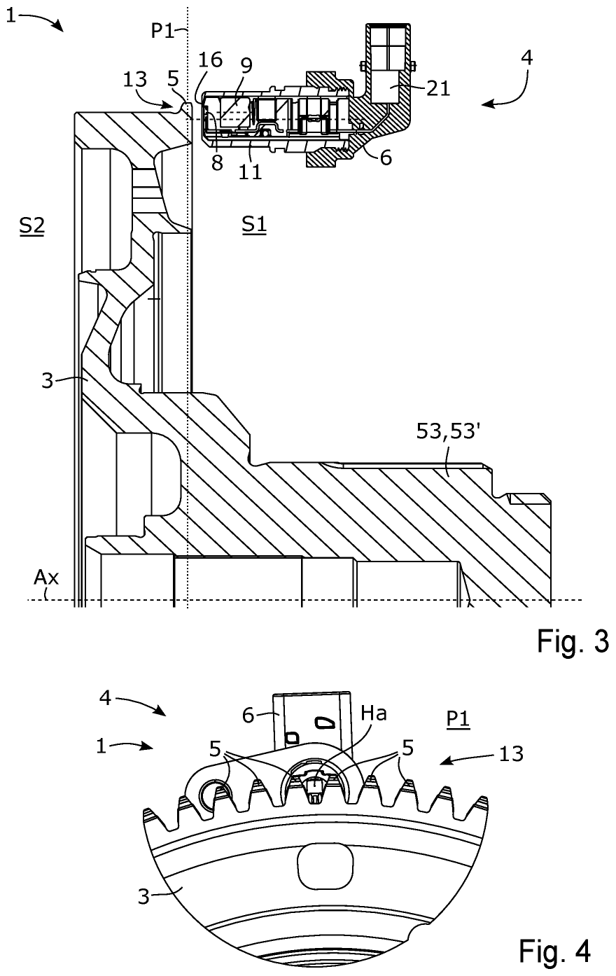

FIG. 3 illustrates a cross section of a vehicle assembly 1 according to some embodiments. According to the illustrated embodiments, the vehicle member 3 is an integral part of the output shaft 53′ of the transmission unit 49 illustrated in FIG. 2. As understood from the above described, the vehicle member 3 may be an integral part of another type of shaft 53 of a vehicle 2 comprising the vehicle assembly 1. Moreover, the vehicle member 3 may be a separate part attached to a shaft 53, 53′ of a vehicle 2 or a transmission unit 49 comprising the vehicle assembly 1.

The vehicle member 3 is configured to rotate around a rotation axis Ax, at least occasionally, during operation of a vehicle 2 comprising the vehicle assembly 1. As understood from the above described, according to the illustrated embodiments, the vehicle member 3 is configured to rotate around a rotation axis Ax when a vehicle 2 comprising the vehicle assembly 1 is moving in a forward or reverse direction relative to a ground surface. The cross section of FIG. 3 is made in a plane comprising the rotation axis ax of the vehicle member 3.

The vehicle assembly 1 comprises a speed measuring arrangement 4 configured to measure a rotational speed of the vehicle member 3. The speed measuring arrangement 4 comprises a set of elements 5 arranged at a portion 13 of the vehicle member 3. As is indicated in FIG. 3, the set of elements 5 is configured to rotate in a first plane P1 upon rotation of the vehicle member 3 around the rotation axis Ax. The first plane P1 may also be referred to as a rotation plane. The first plane P1 is perpendicular to the rotation axis Ax of the vehicle member 3.

The speed measuring arrangement 4 further comprises a speed sensor unit 6. The speed sensor unit 6 comprises an end section 16 facing the portion 13 of the vehicle member 3 from a first side S1 of the first plane P1. The end section 16 of the speed sensor unit 6 is a distal end section of the speed sensor unit 6. According to the illustrated embodiments, the entire speed sensor unit 6 is arranged on the first side S1 of the first plane P1.

FIG. 4 illustrates an isometric view of a portion of the vehicle assembly 1 illustrated in FIG. 3. In FIG. 4, the vehicle assembly 1 is illustrated as seen from a second side S2 of the first plane P1 in a viewing direction parallel to the rotation axis Ax of the vehicle member 3. The first plane P1 and the rotation axis Ax of the vehicle member 3 are indicated in FIG. 3.

The set of elements 5 can be more clearly seen in FIG. 4. According to embodiments herein, each element 5 of the set of elements 5 comprises a ferromagnetic material, such as steel, aluminium, or the like. Moreover, the elements 5 of the set of elements 5 are distributed at least substantially equidistantly at the portion 13 of the vehicle member 3 and such that void spaces are formed between each pair of adjacent elements 5 of the set of elements 5. According to the embodiments illustrated in FIG. 4, the elements 5 are formed as teeth and are made of steel. According to further embodiments, the elements 5 may have another shape and may comprise another type of ferromagnetic material.

Below, simultaneous reference is made to FIG. 1-FIG. 4, if not indicated otherwise. As understood from the above described, the portion 13 of the vehicle member 3, at which the set of elements 5 is arranged, is an annular portion of the vehicle member 3. Furthermore, each element 5 of the set of elements 5 obtains an orbital movement around the rotation axis Ax of the vehicle member 3 at a predetermined radius from the rotation axis Ax upon rotation of the vehicle member 3 around the rotation axis Ax. Moreover, the vehicle member 3 and the speed sensor unit 6 are arranged such that the end section 16 of the speed sensor unit 6 is positioned substantially at the predetermined radius from the rotation axis Ax of the vehicle member 3. In other words, the vehicle member 3 and the speed sensor unit 6 are arranged such that each element 5 of the set of elements 5 passes in front of the end section 16 of the speed sensor unit 6 upon rotation of the vehicle member 3 around the rotation axis Ax.

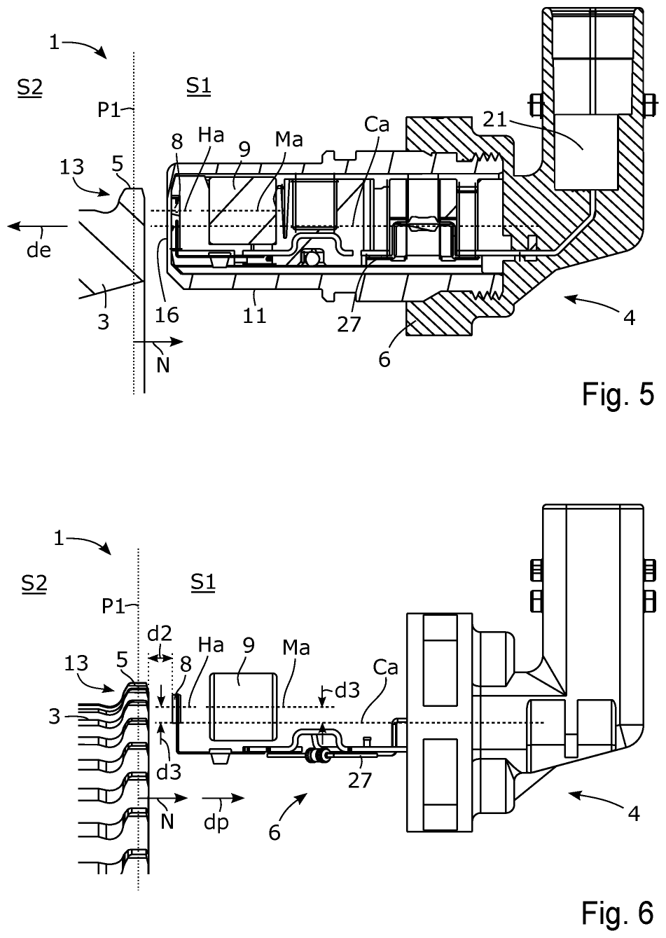

FIG. 5 illustrates an enlarged cross section of the vehicle assembly 1 illustrated in FIG. 3 and FIG. 4. As mentioned, the speed sensor unit 6 comprises an end section 16 facing the portion 13 of the vehicle member 3 from a first side S1 of the first plane P1. Moreover, according to embodiments herein, the speed sensor unit 6 comprises a Hall sensor 8 arranged at the end section 16 of the speed sensor unit 6. The Hall sensor 8 is also indicated in FIG. 3.

Moreover, the speed sensor unit 6 comprises a magnet 9. The Hall sensor 8 is arranged between the magnet 9 and the portion 13 of the vehicle member 3. The Hall sensor 8 may also be referred to as a Hall effect sensor and is a type of sensor which detects the presence and magnitude of a magnetic field using the Hall effect. The Hall sensor 8 is configured to provide a voltage proportional to the strength of the magnetic field at the location of the Hall sensor 8. The voltage of the Hall sensor 8 may also be referred to as an output voltage of the Hall sensor 8.

Since the vehicle member 3 and the speed sensor unit 6 are arranged such that the elements 5 of the set of elements 5 passes in front of the end section 16 of the speed sensor unit 6 upon rotation of the vehicle member 3 around the rotation axis Ax, a varying magnetic field is provided at the location of the Hall sensor 8 upon rotation of the vehicle member 3 around the rotation axis Ax. Accordingly, in this manner, a varying voltage of the Hall sensor 8 is provided upon rotation of the vehicle member 3.

The vehicle assembly 1 further comprises a control unit 21 and an electric circuit 27 connecting the control unit 21 to the Hall sensor 8. The control unit 21 is configured to provide data representative of the rotational speed of the vehicle member 3 by monitoring the voltage of the Hall sensor 8. According to the illustrated embodiments, each of the control unit 21 and the electric circuit 27 is arranged in the speed sensor unit 6. However, according to further embodiments, one or both of the control unit 21 and the electric circuit 27 may be arranged at least partially outside of the speed sensor unit 6.

As is indicated in FIG. 3 and FIG. 5, the speed sensor unit 6 comprises an elongated sensor portion 11. Moreover, as is indicated in FIG. 5, the elongated sensor portion 11 is elongated along a direction of elongation de. The elongated sensor portion 11 of the speed sensor unit 6 comprises the end section 16 of the speed sensor unit 6. According to the illustrated embodiments, the elongated sensor portion 11 of the speed sensor unit 6 is cylindrical. In more detail, according to the illustrated embodiments, the elongated sensor portion 11 of the speed sensor unit 6 has a circular cross section in a plane perpendicular to the direction of elongation de of the elongated sensor portion 11. According to further embodiments, the elongated sensor portion 11 of the speed sensor unit 6, may have another shape. As an example, the elongated sensor portion 11 of the speed sensor unit 6 may have an at least substantially oval cross section in a plane perpendicular to the direction of elongation de of the elongated sensor portion 11.

According to the illustrated embodiments, the speed sensor unit 6 is arranged relative to the vehicle member 3 such that the direction of elongation de of the elongated sensor portion 11 is perpendicular to the first plane P1. In other words, according to the illustrated embodiments, the direction of elongation de of the elongated sensor portion 11 is parallel to a normal vector N to the first plane P1. According to further embodiments, the speed sensor unit 6 may be arranged relative to the vehicle member 3 such that the angle between the direction of elongation de of the elongated sensor portion 11 and a normal vector N to the first plane P1 is less than 30 degrees or is less than 10 degrees.

In FIG. 5, a magnet axis Ma of the magnet 9 is indicated. The magnet axis Ma of the magnet 9 can be defined as an imaginary straight line passing through each of the two poles of the magnet 9. According to the illustrated embodiments, the magnetic axis Ma of the magnet 9 extends through the Hall sensor 8 and through the portion 13 of the vehicle member 3.

Moreover, as seen in FIG. 5, according to the illustrated embodiments, the magnet axis Ma of the magnet 9 is parallel to the direction of elongation de of the elongated sensor portion 11 of the speed sensor unit 6. Moreover, the vehicle assembly 1 is arranged such that the magnetic axis Ma of the magnet 9 is perpendicular to the first plane P1. In other words, according to the illustrated embodiments, the magnetic axis Ma of the magnet 9 is parallel to the normal vector N to the first plane P1. According to further embodiments, the vehicle assembly 1 may be arranged such that the angle between the magnetic axis Ma of the magnet 9 and a normal vector N to the first plane P1 is less than 30 degrees or is less than 10 degrees.

According to the illustrated embodiments, the magnetic axis Ma of the magnet 9 coincides with a Hall sensor axis Ha of the Hall sensor 8. In other words, the magnetic axis Ma of the magnet 9 extends through the Hall sensor axis Ha of the Hall sensor 8, and vice versa. The Hall sensor axis Ha of the Hall sensor 8 is also indicated in FIG. 4.

In FIG. 5, a geometrical center axis Ca of the elongated sensor portion 11 is indicated. The geometrical center axis Ca can be defined as an imaginary straight line extending through a geometrical center of the elongated sensor portion 11. The geometrical center axis Ca of the elongated sensor portion 11 is parallel to the direction of elongation de of the elongated sensor portion 11. Moreover, according to the illustrated embodiments, the geometrical center axis Ca of the elongated sensor portion 11 is parallel to the normal vector N to the first plane P1. As mentioned, according to the illustrated embodiments, the elongated sensor portion 11 of the speed sensor unit 6 is cylindrical. According to these embodiments, the geometrical center axis Ca of the elongated sensor portion 11 coincides with a cylinder axis about which the elongated sensor portion 11 is cylindrical.

FIG. 6 illustrates a sectional view of the vehicle assembly 1 illustrated in FIG. 5. In FIG. 6, some components of the speed sensor unit 6 have been omitted for reasons of clarity.

As is indicated in FIG. 6, and as also can be seen in FIG. 5, each of the Hall sensor axis Ha of the Hall sensor 8 and the magnetic axis Ma of the magnet 9 is located a distance d3 from the geometrical center axis Ca of the elongated sensor portion 11. According to the illustrated embodiments, the distance d3 between the geometrical center axis Ca and each of the sensor axis Ha and the magnetic axis Ma is approximately 1.9 mm. According to further embodiments, the distance d3 between the geometrical center axis Ca and each of the sensor axis Ha and the magnetic axis Ma may be within the range of 0.3-10 mm, or may be within the range of 1-4 mm.

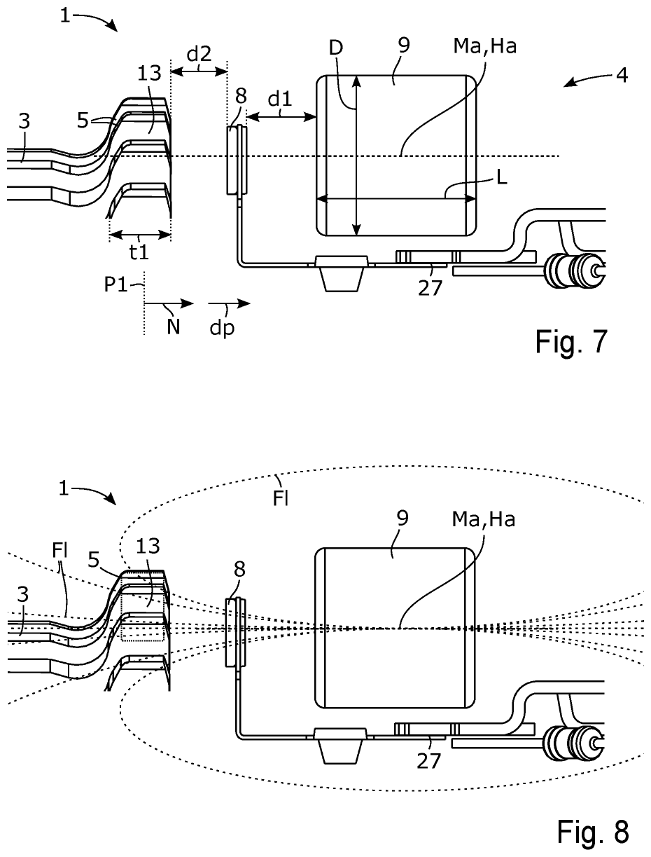

FIG. 7 illustrates an enlarged view of the sectional view of the vehicle assembly 1 illustrated in FIG. 6. As is indicated in FIG. 7, and as also can be seen in FIG. 3, FIG. 5, and FIG. 6, the magnet 9 is arranged at a distance d1 from the Hall sensor 8 measured along a direction dp perpendicular to the first plane P1. Obviously, the direction dp perpendicular to the first plane P1 is parallel to the normal vector N to the first plane P1.

According to the illustrated embodiments, the distance d1 between the magnet 9 and the Hall sensor 8 is approximately 3.5 mm. According to further embodiments, the distance d1 between the magnet 9 and the Hall sensor 8 may be within the range of 1-7 mm, or may be within the range of 2.5-5.5 mm.

Below, simultaneous reference is made to FIG. 3-FIG. 7, if not indicated otherwise. According to the embodiments illustrated in FIG. 3-FIG. 7, the magnet 9 is a relatively strong magnet which provides a magnetic flux density at the end section 16 of the speed sensor unit 6 exceeding 40 Gauss. According to further embodiments, the magnet 9 may provide a magnetic flux density at the end section 16 exceeding 35 Gauss.

That is, according to the illustrated embodiments, the magnet 9 is arranged at a distance from the end section 16 of the speed sensor unit 6 and has a magnetic strength and orientation such that the magnetic flux density at the end section 16 exceeds 40 Gauss. The magnetic flux density at the end section 16 may be measured at an outer surface of the end section 16 of the speed sensor unit 6. According to the illustrated embodiments, the distance between the Hall sensor 8 and the outer surface of the end section 16 of the speed sensor unit 6 is approximately 0.5 mm as measured in a direction parallel to the magnetic axis Ma of the magnet 9. In other words, according to the illustrated embodiments, the distance between the magnet 9 the outer surface of the end section 16 of the speed sensor unit 6 is approximately 4 mm, as measured in a direction parallel to the magnetic axis Ma of the magnet 9.

According to the illustrated embodiments, the magnet 9 is a neodymium magnet, which also can be referred to as a NdFeB magnet. Moreover, according to the illustrated embodiments, the magnet 9 has a cylindrical shape, wherein a cylinder axis of the cylindrical shape coincides with the magnetic axis Ma of the magnet 9. Furthermore, according to the illustrated embodiments, the diameter D of the magnet 9 is approximately 8 mm and a length L of the magnet 9 is approximately 8 mm. The length L of the magnet 9 can be measured in a direction parallel to the magnetic axis Ma of the magnet 9 whereas the diameter D of the magnet 9 can be measured in a direction perpendicular to the magnetic axis Ma of the magnet 9. According to further embodiments, the speed sensor unit 6 may comprise another type of magnet. Moreover, the magnet may have another type of shape and measurements than described above.

FIG. 8 illustrates the enlarged view of the sectional view of the vehicle assembly 1 illustrated in FIG. 7. A number of magnetic field lines Fl are depicted in FIG. 8. The magnetic field lines Fl indicates the directions of the magnetic field generated by the magnet 9.

Below, simultaneous reference is made to FIG. 1-FIG. 8, if not indicated otherwise. Due to the properties of the magnet 9, the orientation thereof, and the relative distance d1 between the magnet 9 and the Hall sensor 8, a telescopic effect is provided in which the magnetic field of the magnet 9 can interact with the set of elements 5 in a more accurate and focused manner so as to obtain more focused and accurate changes in magnetic flux density at the position of the Hall sensor 8 upon rotation of the vehicle member 3 around the rotation axis Ax. As seen in FIG. 8, the telescopic effect allows a more concentrated concentric part of the magnetic field of the magnet 9 to interact with elements 5 at the concentrated concentric part of the magnetic field in a more accurate and focused manner while reducing changes in the magnetic flux density at the position of the Hall sensor 8 caused by vibrating and/or oscillating elements 5 further from the concentrated concentric part of the magnetic field of the magnet 9. The concentrated concentric part of the magnetic field, as referred to herein, may be a part of the magnetic field of the magnet 9 at the portion 13 of the vehicle member 3, wherein the concentrated concentric part of the magnetic field is concentric around the magnetic axis Ma of the magnet 9.

In other words, due to the properties of the magnet 9, the orientation thereof, and the relative distance d1 between the magnet 9 and the Hall sensor 8, i.e., due to the telescopic effect explained above, a more focused sensing area can be obtained at the portion 13 of the vehicle member 3, wherein elements 5 inside the sensing area has a greater impact on the magnetic flux density at the position of the Hall sensor 8 than elements 5 outside of the sensing area. Moreover, the telescopic effect explained above is capable of increasing the impact on the magnetic flux density at the position of the Hall sensor 8 caused by the elements 5 inside the focused sensing area and is capable of reducing the impact on the magnetic flux density at the position of the Hall sensor 8 caused by the elements 5 outside the focused sensing area.

In this manner, conditions are provided for a speed measuring arrangement 4 being less sensitive to variations in the relative distance between the end section 16 of the speed sensor unit 6 and the portion 13 of the vehicle member 3. Moreover, conditions are provided for a speed measuring arrangement 4 being less sensitive to vibration and oscillation of the vehicle member 3.

Accordingly, in this manner, the rotational speed of the output shaft 53′ of the transmission unit 49 illustrated in FIG. 2 can be measured in an efficient, robust, and reliable manner. Since the rotation of the output shaft 53′ of the transmission unit 49 is indicative of a movement of the vehicle 2 relative to a ground surface, the movement speed of the vehicle 2 can be measured in an efficient, robust, and reliable manner. The output shaft 53′ of the transmission unit 49 may for example be subjected to oscillation and/or vibration when the vehicle 2 is at stand still with the power source 51 operating and the transmission unit 49 being in a neutral gear and/or with the clutch 55 in a disengaged state. Such oscillation and/or vibration may be transferred to the vehicle member 3.

However, due to the telescopic effect allowing the magnetic field of the magnet 9 to interact with the set of elements 5 in a more accurate and focused manner, the generation of a varying voltage in the Hall sensor 8 can be avoided upon oscillation and/or vibration of the vehicle member 3. As a further result, misinterpretation of data from the Hall sensor 8 as movement of the vehicle 2 can be avoided.

Furthermore, the output shaft 53′ of the transmission unit 49 may be subjected to slight variations in the axial position thereof for example during gear changes in the transmission unit 49. Such variations in the axial position of the output shaft 53′ may be transferred to the vehicle member 3.

However, due to the telescopic effect allowing the magnetic field of the magnet 9 to interact with the set of elements 5 in a more accurate and focused manner also at greater distances from the end section 16 of the speed sensor unit 6, the relative distance between the end section 16 of the speed sensor unit 6 and the vehicle member 3 is allowed to vary without significantly impairing the measurement efficiency of the speed measuring arrangement 4.

In addition, the telescopic effect explained above provides enhanced conditions for arranging the speed sensor unit 6 such that the end section 16 thereof faces the portion 13 of the vehicle member 3 from the first side S1 of the first plane P1, i.e., such that the speed sensor unit 6 is arranged at least partially axially relative to the vehicle member 3. That is, in prior art speed measuring arrangements, the speed sensor unit is arranged radially relative to a toothed wheel, i.e., such that the rotation plane of teeth of the toothed wheel, i.e., a plane corresponding to the first plane P1, extends through the end section at which a sensor is arranged. Since the telescopic effect explained above provides enhanced conditions for the herein described relative orientation between the speed sensor unit 6 and the vehicle member 3, packing problems in vehicles 2 comprising the vehicle assembly 1 may be at least partially alleviated.

As explained above, the vehicle member 3 may be an integral part of another type of shaft 53 of a vehicle 2 comprising the vehicle assembly 1 or may be connected to another type of shaft 53 of a vehicle 2 comprising the vehicle assembly 1. According to such embodiments, the speed measuring arrangement 4 is capable of measuring the rotational speed of such a shaft 53 in an efficient, robust, and reliable manner according to the above.

In FIG. 6 and FIG. 7, the distance d2 between the Hall sensor 8 and the portion 13 of the vehicle member 3 is indicated. According to the embodiments illustrated in FIG. 3-FIG. 8, distance d2 between the Hall sensor 8 and the portion 13 of the vehicle member 3 is approximately 81.3% of the distance d1 between the magnet 9 and the Hall sensor 8, measured along a direction dp perpendicular to the first plane P1. In other words, according to the illustrated embodiments, the distance d1 between the magnet 9 and the Hall sensor 8 is greater than a distance d2 between the Hall sensor 8 and the portion 13 of the vehicle member 3, measured along a direction dp perpendicular to the first plane P1.

Moreover, according to the illustrated embodiments, the distance d1 between the magnet 9 and the Hall sensor 8 is approximately 123% of the distance d2 between the Hall sensor 8 and the portion 13 of the vehicle member 3, measured along a direction dp perpendicular to the first plane P1. According to further embodiments, the distance d1 between the magnet 9 and the Hall sensor 8 may be within the range of 10%-230%, or may be within the range of 85%-165%, of the distance d2 between the Hall sensor 8 and the portion 13 of the vehicle member 3, measured along a direction dp perpendicular to the first plane P1.

Due to the telescopic effect explained above, the relatively great distances d2 between the Hall sensor 8 and the portion 13 of the vehicle member 3 can be used without significantly impairing the measurement efficiency of the speed measuring arrangement 4.

As is indicated in FIG. 7, according to the illustrated embodiments, the distance d1 between the magnet 9 and the Hall sensor 8 is greater than a thickness t1 of the portion 13 of the vehicle member 3, measured along a direction dp perpendicular to the first plane P1. The thickness t1 of the portion 13 of the vehicle member 3 may be determined by measuring the thickness of the elements 5 of the set of elements 5 along a direction dp perpendicular to the first plane P1. The thickness t1 of the portion 13 of the vehicle member 3 may also be referred to as a width of the portion 13 of the vehicle member 3 measured along a direction dp perpendicular to the first plane P1. The thickness t1 of the portion 13 of the vehicle member 3, as referred to herein, may be a maximum thickness of the portion 13 of the vehicle member 3 measured along a direction dp perpendicular to the first plane P1.

In FIG. 6-FIG. 8, portions of the electrical circuit 27 can be more clearly seen. The electrical circuit 27 may comprise electrical conductors and a number of electrical components, such as one or more resistors, capacitors, and the like.

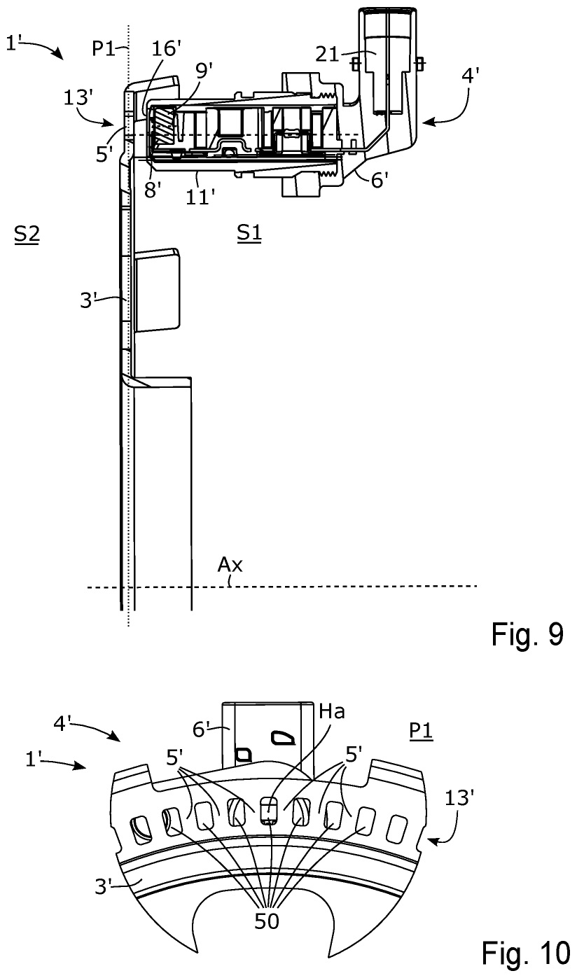

FIG. 9 illustrates a cross section of a vehicle assembly 1′ according to some further embodiments. The powertrain 44 illustrated in FIG. 2 may comprise a vehicle assembly 1′ according to the embodiments illustrated in FIG. 9. Below, simultaneous reference is made to FIG. 1, FIG. 2, and FIG. 9, if not indicated otherwise. The vehicle assembly 1′ comprises a vehicle member 3′ is configured to rotate around a rotation axis Ax, at least occasionally, during operation of a vehicle 2 comprising the vehicle assembly 1′. The cross section of FIG. 9 is made in a plane comprising the rotation axis ax′ of the vehicle member 3′.

The vehicle member 3′ may be connected to a shaft 53, 53′ of the transmission unit 49 of the powertrain 44, such as an output shaft 53′ of the transmission unit 49 or another type of shaft 53 of the transmission unit 49. According to the embodiments illustrated in FIG. 9, the vehicle member 3′ is a separate part configured to be attached to, and/or connected to, a shaft 53, 53′ of a vehicle 2 comprising the vehicle assembly 1′.

The vehicle assembly 1′ comprises a speed measuring arrangement 4′ configured to measure a rotational speed of the vehicle member 3′. The speed measuring arrangement 4′ comprises a set of elements 5′ arranged at a portion 13′ of the vehicle member 3′. As is indicated in FIG. 9, the set of elements 5′ is configured to rotate in a first plane P1 upon rotation of the vehicle member 3′ around the rotation axis Ax. The first plane P1 may also be referred to as a rotation plane. The first plane P1 is perpendicular to the rotation axis Ax of the vehicle member 3′.

The speed measuring arrangement 4′ further comprises a speed sensor unit 6′. The speed sensor unit 6′ comprises an end section 16′ facing the portion 13′ of the vehicle member 3′ from a first side S1 of the first plane P1. The end section 16′ of the speed sensor unit 6′ is a distal end section of the speed sensor unit 6′. According to the illustrated embodiments, the entire speed sensor unit 6′ is arranged on the first side S1 of the first plane P1.

FIG. 10 illustrates an isometric view of a portion of the vehicle assembly 1′ illustrated in FIG. 9. In FIG. 10, the vehicle assembly 1′ is illustrated as seen from a second side S2 of the first plane P1 in a viewing direction parallel to the rotation axis Ax of the vehicle member 3′. The first plane P1 and the rotation axis Ax of the vehicle member 3′ are indicated in FIG. 9.

The set of elements 5′ can be more clearly seen in FIG. 10. According to the embodiments illustrated in FIG. 9 and FIG. 10, the vehicle member 3′ is provided from a piece of sheet material, wherein a number of apertures 50 is provided in the sheet material, and wherein each element 5′ of the set of elements 5′ constitutes a piece of material between two adjacent apertures 50 of the number of apertures 50. According to the illustrated embodiments, the vehicle member 3′ is provided from a sheet of an aluminium alloy, i.e., a ferromagnetic material. According to further embodiments, the vehicle member 3′ may be provided from a sheet of another type of a ferromagnetic material, such as steel.

Moreover, the apertures 50 of the number of apertures 50 are distributed at least substantially equidistantly at the portion 13′ of the vehicle member 3′ such that at least substantially equally sized elements 5 are formed between each pair of adjacent apertures 50.

Below, simultaneous reference is made to FIG. 1, FIG. 2, FIG. 9, and FIG. 10, if not indicated otherwise. As understood from the above described, the portion 13′ of the vehicle member 3′, at which the set of elements 5′ is arranged, is an annular portion of the vehicle member 3′. Furthermore, each element 5′ of the set of elements 5′ obtains an orbital movement around the rotation axis Ax of the vehicle member 3′ at a predetermined radius from the rotation axis Ax upon rotation of the vehicle member 3′ around the rotation axis Ax. Moreover, the vehicle member 3′ and the speed sensor unit 6′ are arranged such that the end section 16′ of the speed sensor unit 6′ is positioned substantially at the predetermined radius from the rotation axis Ax of the vehicle member 3′. In other words, the vehicle member 3′ and the speed sensor unit 6′ are arranged such that each element 5′ of the set of elements 5′ passes in front of the end section 16′ of the speed sensor unit 6′ upon rotation of the vehicle member 3′ around the rotation axis Ax.

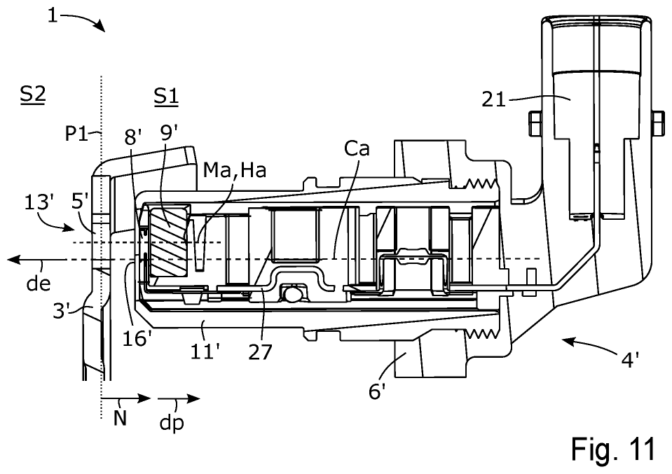

FIG. 11 illustrates an enlarged cross section of the vehicle assembly 1′ illustrated in FIG. 9 and FIG. 10. As mentioned, the speed sensor unit 6′ comprises an end section 16′ facing the portion 13′ of the vehicle member 3′ from a first side S1 of the first plane P1. Moreover, according to embodiments herein, the speed sensor unit 6′ comprises a Hall sensor 8′ arranged at the end section 16′ of the speed sensor unit 6′. The Hall sensor 8′ is also indicated in FIG. 9.

Moreover, the speed sensor unit 6′ comprises a magnet 9′. The Hall sensor 8′ is arranged between the magnet 9′ and the portion 13′ of the vehicle member 3′. The Hall sensor 8′ may also be referred to as a Hall effect sensor and is a type of sensor which detects the presence and magnitude of a magnetic field using the Hall effect. The Hall sensor 8′ is configured to provide a voltage proportional to the strength of the magnetic field at the location of the Hall sensor 8′. The voltage of the Hall sensor 8′ may also be referred to as an output voltage of the Hall sensor 8′.

Since the vehicle member 3′ and the speed sensor unit 6′ are arranged such that the elements 5 of the set of elements 5′ passes in front of the end section 16′ of the speed sensor unit 6′ upon rotation of the vehicle member 3′ around the rotation axis Ax, a varying magnetic field is provided at the location of the Hall sensor 8′ upon rotation of the vehicle member 3′ around the rotation axis Ax. Accordingly, in this manner, a varying voltage of the Hall sensor 8′ is provided upon rotation of the vehicle member 3′.

The vehicle assembly 1′ comprises a control unit 21 and an electric circuit 27 connecting the control unit 21 to the Hall sensor 8′. The control unit 21 is configured to provide data representative of the rotational speed of the vehicle member 3′ by monitoring the voltage of the Hall sensor 8′. According to the illustrated embodiments, each of the control unit 21 and the electric circuit 27 is arranged in the speed sensor unit 6′. However, according to further embodiments, one or both of the control unit 21 and the electric circuit 27 may be arranged at least partially outside of the speed sensor unit 6′.

As is indicated in FIG. 9 and FIG. 11, the speed sensor unit 6′ comprises an elongated sensor portion 11′. Moreover, as is indicated in FIG. 11, the elongated sensor portion 11′ is elongated along a direction of elongation de. The elongated sensor portion 11′ of the speed sensor unit 6′ comprises the end section 16′. According to the illustrated embodiments, the elongated sensor portion 11′ of the speed sensor unit 6′ is cylindrical. However, according to further embodiments, the elongated sensor portion 11′ of the speed sensor unit 6′ may have another shape, such as a shape having an at least substantially oval cross section in a plane perpendicular to direction of elongation de elongated sensor portion 11′, or the like.

According to the illustrated embodiments, the speed sensor unit 6′ is arranged relative to the vehicle member 3′ such that the direction of elongation de of the elongated sensor portion 11′ is perpendicular to the first plane P1. In other words, according to the illustrated embodiments, the direction of elongation de of the elongated sensor portion 11′ is parallel to a normal vector N to the first plane P1. According to further embodiments, the speed sensor unit 6′ may be arranged relative to the vehicle member 3′ such that the angle between the direction of elongation de of the elongated sensor portion 11′ and a normal vector N to the first plane P1 is less than 30 degrees or is less than 10 degrees.

In FIG. 11, a magnet axis Ma of the magnet 9′ is indicated. The magnet axis Ma of the magnet 9′ can be defined as an imaginary straight line passing through each of the two poles of the magnet 9′. According to the illustrated embodiments, the magnetic axis Ma of the magnet 9′ extends through the Hall sensor 8′ and through the portion 13′ of the vehicle member 3′.

Moreover, as seen in FIG. 11, according to the illustrated embodiments, the magnet axis Ma of the magnet 9′ is parallel to the direction of elongation de of the elongated sensor portion 11′ of the speed sensor unit 6′. Moreover, the vehicle assembly 1′ is arranged such that the magnetic axis Ma of the magnet 9′ is perpendicular to the first plane P1. In other words, according to the illustrated embodiments, the magnetic axis Ma of the magnet 9′ is parallel to the normal vector N to the first plane P1. According to further embodiments, the vehicle assembly 1′ may be arranged such that the angle between the magnetic axis Ma of the magnet 9′ and a normal vector N to the first plane P1 is less than 30 degrees or is less than 10 degrees.

According to the illustrated embodiments, the magnetic axis Ma of the magnet 9′ coincides with a Hall sensor axis Ha of the Hall sensor 8′. In other words, the magnetic axis Ma of the magnet 9′ passes through the Hall sensor axis Ha of the Hall sensor 8′, and vice versa. The Hall sensor axis Ha of the Hall sensor 8′ is also indicated in FIG. 10.

In FIG. 11, a geometrical center axis Ca of the elongated sensor portion 11′ is indicated. The geometrical center axis Ca can be defined as an imaginary straight line extending through a geometrical center of the elongated sensor portion 11′. The geometrical center axis Ca of the elongated sensor portion 11′ is parallel to the direction of elongation de of the elongated sensor portion 11′. Moreover, according to the illustrated embodiments, the geometrical center axis Ca of the elongated sensor portion 11′ is parallel to the normal vector N to the first plane P1. As mentioned, according to the illustrated embodiments, the elongated sensor portion 11′ of the speed sensor unit 6′ is cylindrical. According to these embodiments, the geometrical center axis Ca of the elongated sensor portion 11′ coincides with a cylinder axis about which the elongated sensor portion 11′ is cylindrical.

According to the embodiments illustrated in FIG. 11, each of the Hall sensor axis Ha of the Hall sensor 8′ and the magnetic axis Ma of the magnet 9′ is located a distance from the geometrical center axis Ca of the elongated sensor portion 11′. According to the illustrated embodiments, the distance between the geometrical center axis Ca and each of the sensor axis Ha and the magnetic axis Ma is approximately 1.9 mm. According to further embodiments, the distance between the geometrical center axis Ca and each of the sensor axis Ha and the magnetic axis Ma may be within the range of 0.3-10 mm, or may be within the range of 1-4 mm.

According to the embodiments illustrated in FIG. 11, the magnet 9′ is arranged at a small distance from the Hall sensor 8′ measured along a direction dp perpendicular to the first plane P1. In more detail, according to the embodiments illustrated in FIG. 11, the magnet 9′ is arranged approximately 0.2 mm from the Hall sensor 8′ measured along a direction dp perpendicular to the first plane P1. According to further embodiments, the distance between the magnet 9′ and the Hall sensor 8′ may be within the range of 0-2.5 mm.

According to the embodiments illustrated in FIG. 9-FIG. 11, the magnet 9′ is arranged at a distance from the end section 16′ of the speed sensor unit 6′ and has a magnetic strength and orientation such that the magnetic flux density at the end section 16′ exceeds 40 Gauss. According to further embodiments, the magnet 9′ may provide a magnetic flux density at the end section 16′ exceeding 35 Gauss. The magnetic flux density at the end section 16′ may be measured at an outer surface of the end section 16′ of the speed sensor unit 6′. According to the illustrated embodiments, the distance between the Hall sensor 8′ and the outer surface of the end section 16′ of the speed sensor unit 6′ is approximately 0.5 mm. In other words, according to the illustrated embodiments, the distance between the magnet 9′ the outer surface of the end section 16′ of the speed sensor unit 6′ is approximately 0.7 mm, as measured in a direction parallel to the magnetic axis Ma of the magnet 9′.

According to the illustrated embodiments, the magnet 9′ is a neodymium magnet, which also can be referred to as a NdFeB magnet. Moreover, according to the illustrated embodiments, the magnet 9′ has a cylindrical shape wherein a cylinder axis of the cylindrical shape coincides with the magnetic axis Ma of the magnet 9′. Furthermore, according to the illustrated embodiments, the diameter of the magnet 9′ is approximately 7.5 mm and a length of the magnet 9′ is approximately 4 mm. The length of the magnet 9′ can be measured in a direction parallel to the magnetic axis Ma of the magnet 9′ whereas the diameter of the magnet 9′ can be measured in a direction perpendicular to the magnetic axis Ma of the magnet 9′. According to further embodiments, the speed sensor unit 6′ may comprise another type of magnet. Moreover, the magnet may have another type of shape and measurements than described above.

Due to the features of the vehicle assembly 1′ according to the embodiments illustrated in FIG. 9-FIG. 11, the vehicle assembly 1′ is capable of measuring the rotational speed of the vehicle member 3′ in a robust, efficient, and reliable manner despite the at least partially axial arrangement of the speed sensor unit 6′ relative to the vehicle member 3′.

It is to be understood that the foregoing is illustrative of various example embodiments and that the invention is defined only by the appended independent claims. A person skilled in the art will realize that the example embodiments may be modified, and that different features of the example embodiments may be combined to create embodiments other than those described herein, without departing from the scope of the present invention, as defined by the appended independent claims.

As used herein, the term “comprising” or “comprises” is open-ended, and includes one or more stated features, elements, steps, components, or functions but does not preclude the presence or addition of one or more other features, elements, steps, components, functions, or groups thereof.

1. A vehicle assembly comprising:
a vehicle member configured to rotate around a rotation axis, at least occasionally, during operation of a vehicle;
a speed measuring arrangement for measuring a rotational speed of the vehicle member, wherein the speed measuring arrangement comprises:
a set of elements arranged at a portion of the vehicle member, wherein the set of elements is configured to rotate in a first plane upon rotation of the vehicle member around the rotation axis; and
a speed sensor unit comprising:
an end section facing the portion of the vehicle member from a first side of the first plane; and
a Hall sensor arranged at the end section of the speed sensor unit.

2. The vehicle assembly according to claim 1, wherein the speed sensor unit comprises a magnet, and wherein the Hall sensor is arranged between the magnet and the portion of the vehicle member.

3. The vehicle assembly according to claim 2, wherein the magnet provides a magnetic flux density at the end section exceeding either one of: 35 Gauss or 40 Gauss.

4. The vehicle assembly according to claim 2, wherein an angle between a normal vector to the first plane and a magnetic axis of the magnet is less than either one of: 30 degrees or 10 degrees.

5. The vehicle assembly according to claim 2, wherein a magnetic axis of the magnet extends through the Hall sensor and the portion of the vehicle member.

6. The vehicle assembly according to claim 2, wherein the magnet is arranged at a distance from the Hall sensor measured along a direction perpendicular to the first plane.

7. The vehicle assembly according to claim 6, wherein the distance between the magnet and the Hall sensor is within the range of either one of: 1-7 mm, or 2.5-5.5 mm.

8. The vehicle assembly according to claim 6, wherein the distance between the magnet and the Hall sensor is within the range of either one of: 10%-230% or 85%-165% of a distance between the Hall sensor and the portion of the vehicle member, measured along a direction perpendicular to the first plane.

9. The vehicle assembly according to claim 6, wherein the distance between the magnet and the Hall sensor is greater than a thickness of the portion of the vehicle member measured along a direction perpendicular to the first plane.

10. The vehicle assembly according to claim 1, wherein the speed sensor unit comprises an elongated sensor portion being elongated along a direction of elongation and comprising the end section, and wherein a angle between the direction of elongation of the elongated sensor portion and a normal vector to the first plane is less than 30 degrees or is less than 10 degrees.

11. The vehicle assembly according to claim 1, wherein the vehicle assembly comprises a control unit and an electric circuit connecting the control unit to the Hall sensor, and wherein the control unit is configured to provide data representative of the rotational speed of the vehicle member by monitoring a voltage of the Hall sensor.

12. The vehicle assembly according to claim 11, wherein each of the control unit and the electric circuit is arranged in the speed sensor unit.

13. The vehicle assembly according to claim 1, wherein the vehicle member of the vehicle assembly is configured to be connected to at least one ground engaging wheel of a vehicle comprising the vehicle assembly.

14. A transmission unit comprising:
a shaft configured to transmit power from a power source to at least one ground engaging wheel of a vehicle;
a vehicle member connected to the shaft and configured to rotate around a rotation axis, at least occasionally, during operation of the vehicle; and
a speed measuring arrangement for measuring a rotational speed of the vehicle member, wherein the speed measuring arrangement comprises:
a set of elements arranged at a portion of the vehicle member, wherein the set of elements is configured to rotate in a first plane upon rotation of the vehicle member around the rotation axis; and
a speed sensor unit comprising:
an end section facing the portion of the vehicle member from a first side of the first plane; and
a Hall sensor arranged at the end section of the speed sensor unit.

15. A vehicle comprising a vehicle assembly comprising:
a vehicle member connected to the shaft and configured to rotate around a rotation axis, at least occasionally, during operation of the vehicle; and
a speed measuring arrangement for measuring a rotational speed of the vehicle member, wherein the speed measuring arrangement comprises:
a set of elements arranged at a portion of the vehicle member, wherein the set of elements is configured to rotate in a first plane upon rotation of the vehicle member around the rotation axis; and
a speed sensor unit comprising:
an end section facing the portion of the vehicle member from a first side of the first plane; and
a Hall sensor arranged at the end section of the speed sensor unit.

16. The transmission unit according to claim 14, wherein the speed sensor unit comprises a magnet, and wherein the Hall sensor is arranged between the magnet and the portion of the vehicle member.

17. The transmission unit according to claim 16, wherein the magnet provides a magnetic flux density at the end section exceeding either one of: 35 Gauss or 40 Gauss.

18. The transmission unit according to claim 16, wherein an angle between a normal vector to the first plane and a magnetic axis of the magnet is less than either one of: 30 degrees or 10 degrees.

19. The transmission unit according to claim 16, wherein a magnetic axis of the magnet extends through the Hall sensor and the portion of the vehicle member.

20. The transmission unit according to claim 16, wherein the magnet is arranged at a distance from the Hall sensor measured along a direction perpendicular to the first plane.
